(19) United States
(12) Patent Application Publication
(10) Pub. No.: US 2006/0209521 A1
(43) Pub. Date: Sep. 21, 2006

(54) Package structure for passive components and manufacturing method thereof

(75) Inventors: Xin-Hua Li, Taoyuan Hsien (TW); Han-Cheng Hsu, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/258,121

(22) Filed: Oct. 26, 2005

(30) Foreign Application Priority Data
Mar. 18, 2005 (TW) 94108347

(51) Int. Cl. H05K 7/06

(52) U.S. Cl. 361/782

(57) ABSTRACT

A package structure for passive components and manufacturing methods thereof. The packaging structure includes a substrate, a plurality of passive components, a plurality of contacts and a casing. The substrate has a first surface and a second surface opposite to the first surface. The contacts are welded on the first surface of the substrate by ball grid array techniques. The casing has an opening. The casing covers and packages the substrate, and the second surface of the substrate is exposed out of the casing.

### BACKGROUND

The invention relates to package structures for passive components and manufacturing method thereof, and in particular, to passive components formed by ball grid array techniques.

As the development of the information technology increases greatly, the need of data processing also increases. Rapid processing and transferring of large amounts of data relies on various precise electronic devices. With change of life style and social demands, electronic devices and components development tend to develop toward miniaturization, multiple functions, high performance and high speed.

Various components in many electronic devices are mainly divided into active components and passive components. Active components can do data calculation and processing and include various integrated circuit chips. The current signal can be enlarged or passed through but cannot be calculated by passive components. Passive components are circuit components that cannot affect the signal, but only pass the signal without change. The most common passive component is a resistor, a capacitor, an inductor, and a rheostat. For example, the resistor is a metal wire wound resistor, a carbon-film fixed resistor, and a chip resistor; the inductor is a transformer, a coil, and a multilayer ceramic inductor; the capacitor is a mica capacitor, a ceramic capacitor, an electrolytic capacitor, and a multilayer ceramic capacitor.

As the semiconductor technology rapidly improves, passive components are becoming miniaturized, effort-saving, and multi-functional. Thus, companies do their best to apply and develop passive component package structure.

FIG. 1A is a schematic view of a conventional transformer before packaging. FIG. 1B is a side elevation of a conventional transformer after packaging. According to a package structure of a transformer module, as shown in FIG. 1A and FIG. 1B, a conventional transformer module 10 includes a transformer 12 and a printed circuit board 20. The inner structure of the transformer 12 is wound by multilayer coils (not shown). After multilayer coils are packaged in an insulating casing 14, a plurality of pins 16 are exposed. The printed circuit board 20 has a plurality of holes 22 corresponding to the pins 16. The number of the holes 22 is equal to that of the pins 16. After inserting the pins 16 of the transformer 12 into the corresponding holes 22 and welding tin on solder joints 18, the manufacturing procedure of the transformer module 10 is complete. The holes 22 of the printed circuit board 20 are formed by machine drilling and must be precisely aligned with the pins 16. Alignment errors occur easily in mass production resulting in defective transformer modules 10; thus, production costs are greatly increased.

To solve the described problems, a conventional technique uses a surface mounting technology (SMT) to manufacture a transformer module. FIG. 2A is a schematic view of another conventional transformer module before packaging. FIG. 2B is a side elevation of the conventional transformer module of FIG. 2A after packaging. As shown in FIG. 2A and FIG. 2B, a transformer module 30 includes a transformer 32 and a printed circuit board 40. The inner structure of the transformer 32 is also wound by multilayer coils (not shown). After multilayer coils are packaged in an insulating casing 34, a plurality of Z-shaped pins 36 are exposed at both sides of the insulating casing 34. A layer of a solder paste 38 is applied on the printed circuit board 40 by using surface mounting technology. The transformer 32 is disposed on the solder paste 38 of the printed circuit board 40. Furthermore, a combination of the transformer 32 and the printed circuit board 40 is sent into a furnace with high temperature and the Z-shaped pins 36 are securely attached to the printed circuit board 40; thus, the manufacturing procedure of the transformer module 30 is complete.

The described manufacturing procedure for packaging the transformer module 30 solves two problems of the transformer 10. One of the problems of the transformer 10 is that the transformer 10 still needs to drill holes. The other problem is that the holes must be precisely aligned with the pins 20. However, the pins 36 are disposed at both sides of the transformer 30, and are disposed extensively on the printed circuit board 40. Thus, the transformer module 30 occupies a larger space, and cannot be received by current small-size components. When a user's power requirement increases, the number of the z-shaped pins 36 of the transformer module 30 also increases. Hence, an improved structural design of the transformer module 30 cannot be achieved in the restricted space.

### SUMMARY

To solve the described problems, the invention provides a ball grid array package technique. The ball grid array package technique enables a package structure for passive components to achieve the smallest total volume under the condition of a semi-finished product.

Package structures for passive components are provided. An exemplary embodiment of a package structure for passive components includes a substrate, a plurality of passive components, a ball grid array, and a casing. The substrate has a first surface and a second surface opposite to the first surface. The passive components are disposed on the first surface of the substrate. The ball grid array is welded on the second surface of the substrate by ball grid array techniques. The casing has an opening. The casing covers and packages the substrate; thus, the second surface of the substrate is exposed via the opening of the casing.

The invention provides a passive components module. The passive components module uses ball grid array techniques to provide electrical connection of the passive components. When power requirements increases, only the numbers of passive components and solder balls are increased. The total volume of original modules remains the same and the structure design is simplified. Consequently, production costs can be reduced.

Passive components modules are provided. An exemplary embodiment of a passive components module includes a substrate, a plurality of passive components, a ball grid array, and a casing. The substrate has a first surface and a second surface opposite to the first surface. The passive components are disposed on the first surface of the substrate. The ball grid array is welded on the first surface of the substrate by ball grid array techniques. The casing has an opening. The casing covers and packages the substrate; thus, the second surface of the substrate is exposed via the opening of the casing.

The invention provides another package method for passive components. The package method enables semi-finished products of package structure for the same passive components to form the smallest package structure.

Package methods for passive components are provided. An exemplary embodiment of a package method for passive components comprises the following steps. First, a substrate having a first surface and a second surface opposite to the first surface is provided. Second, a plurality of passive components are disposed on the first surface and a plurality of solder balls are welded on the second surface by ball grid array techniques to form a semi-finished product. Last, a casing having an opening is used to cover and package the semi-finished product and the second surface of the substrate is exposed by the opening of the casing.

### DESCRIPTION OF THE DRAWINGS

The invention can be more fully understood by reading the subsequent detailed description and examples with references made to the accompanying drawings, wherein:

FIG. 1A is a schematic view of a conventional transformer module before packaging;

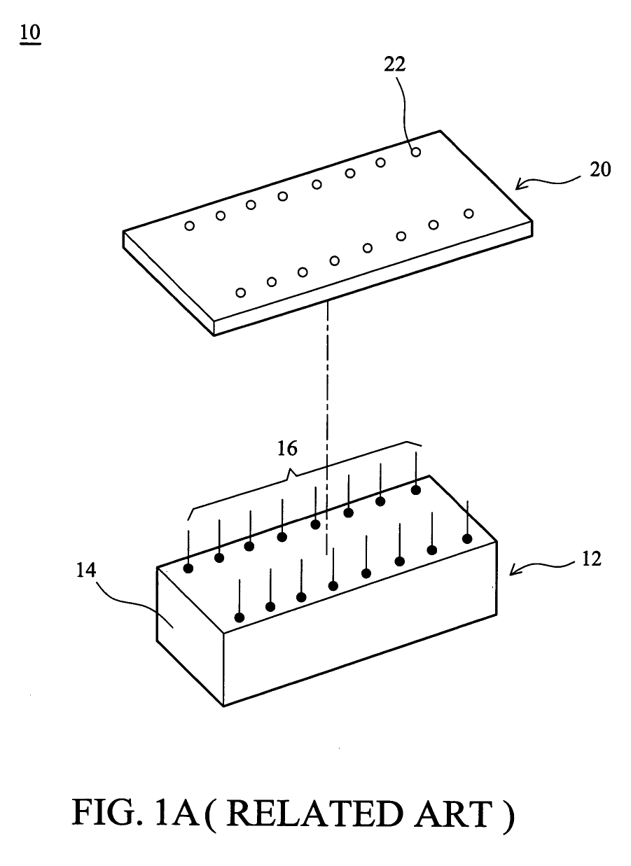

FIG. 1B is a side elevation of a conventional transformer module after packaging;

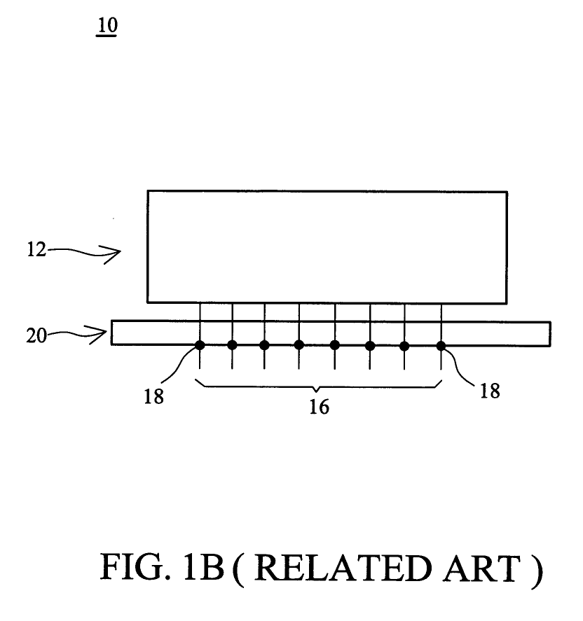

FIG. 2A is a schematic view of another conventional transformer module before packaging;

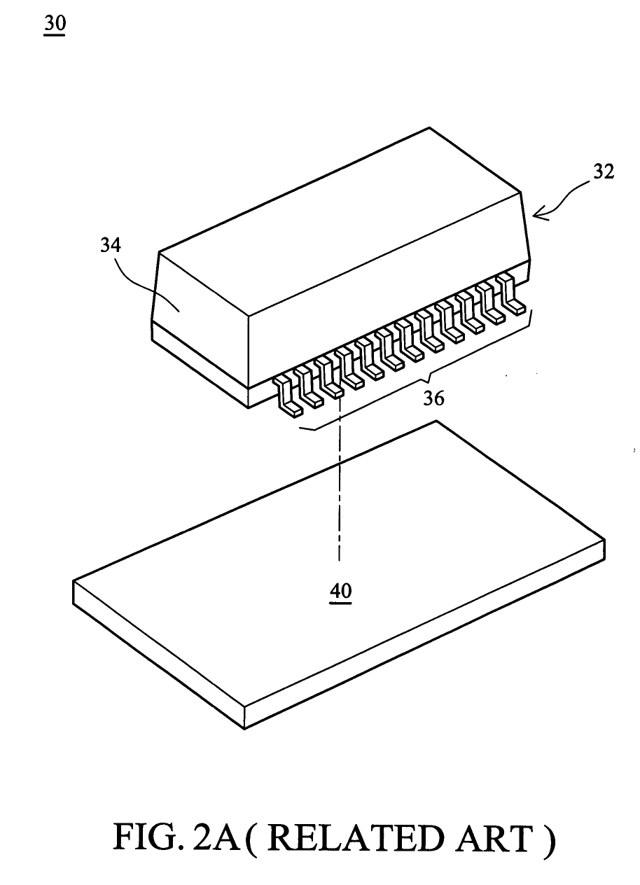

FIG. 2B is a side elevation of the transformer module of FIG. 2A after packaging;

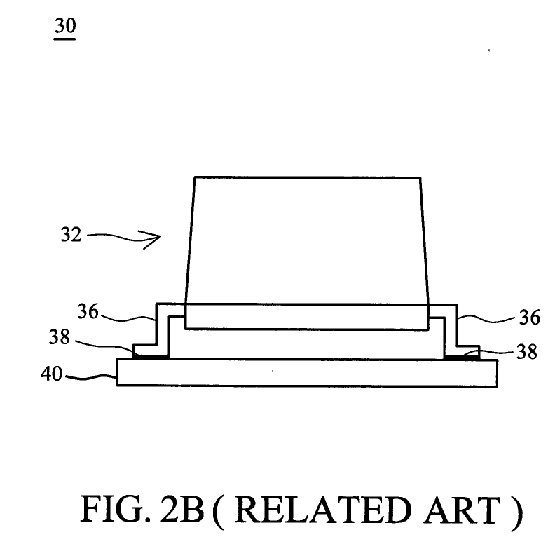

FIG. 3A and FIG. 3B are schematic views of an embodiment of a transformer module;

FIG. 4A is a schematic view of an embodiment of a transformer module before the packaging steps; and

FIG. 4B is a schematic view of an embodiment of a transformer module when the packaging steps are complete.

### DETAILED DESCRIPTION

A package structure for passive components and manufacturing method thereof is disclosed in detail in the following. An exemplary embodiment of a transformer of passive component is provided to expound the essence of the invention.

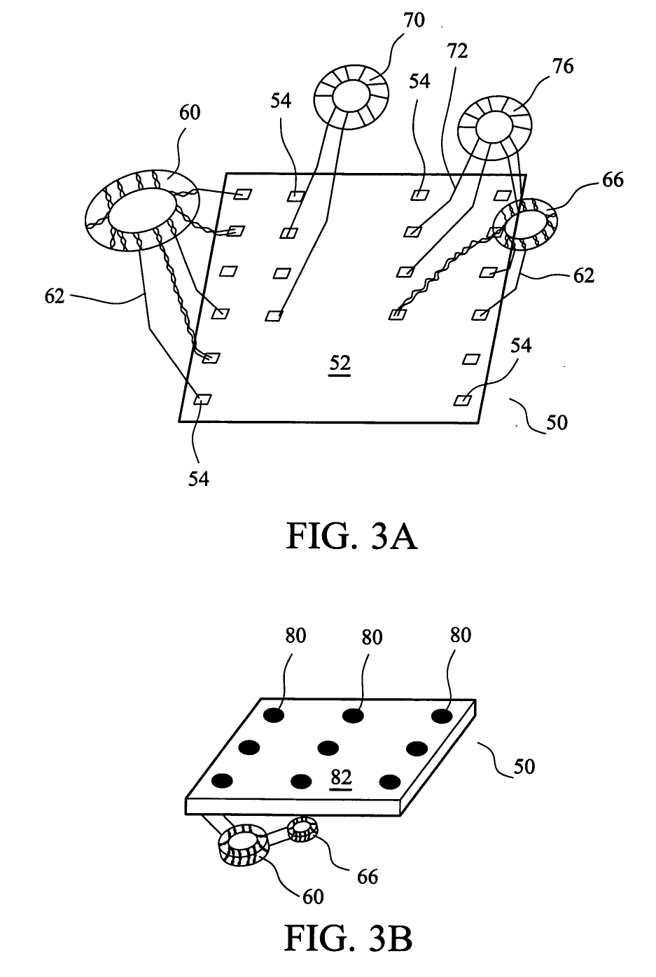

FIG. 3A and FIG. 3B are schematic views of an embodiment of a transformer module according to the present invention. As shown in FIG. 3A and FIG. 3B, a transformer module 100 includes a substrate 50 and a plurality of annular iron cores 60, 66, 70 and 76.

The annular iron cores 60, 66, 70, and 76 are wound by at least two coils 62 to be used as a primary winding and a secondary winding of the transformer. The substrate 50 is a printed circuit board, and has a first surface 52 and a second surface 82 opposite to the first surface 52. First, a plurality of metal sheets 54 made of copper or copper alloy materials are disposed on the first surface 52. The metal sheets 54 are used as the pad welded by the coils 62. Second, a primary outlet terminal and a secondary outlet terminal of the coils 62 wound on the iron cores 60, 66, 70 and 76 are welded on the different metal sheets 54. Last, a plurality of solder balls 80 are welded on the second surface 82 by ball grid array techniques. Each solder ball 80 corresponds to each metal sheet 54. The number of the metal sheets 54 on the first surface 52 is equal to or greater than that of solder balls 80 on the second surface 82.

A high-density solder ball array is welded on the second surface 82 by ball grid array techniques. Thus, when the power requirement of the transformer increases, only the number of iron cores is increased. Additionally, outlet terminals of the coils 62 wound on the iron cores 60, 66, 70 and 76 are welded on the different metal sheets 54. At last, the solder balls 80 are electrically connected to the metal sheets 54 and the power requirement of the transformer module is achieved.

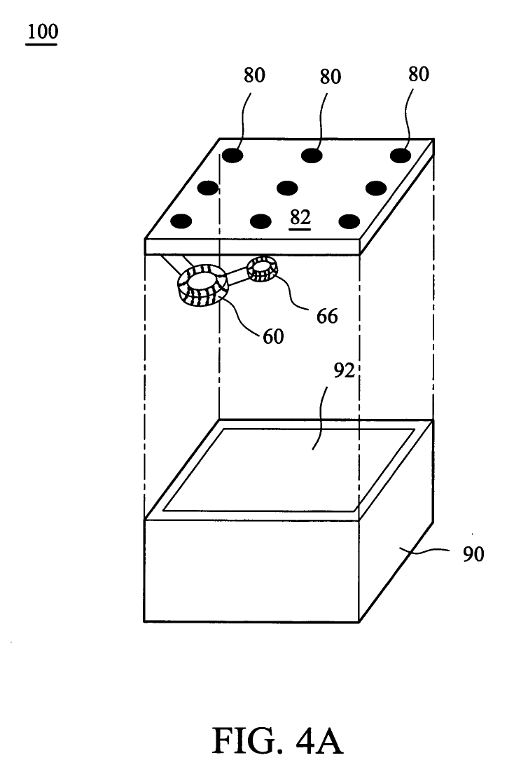

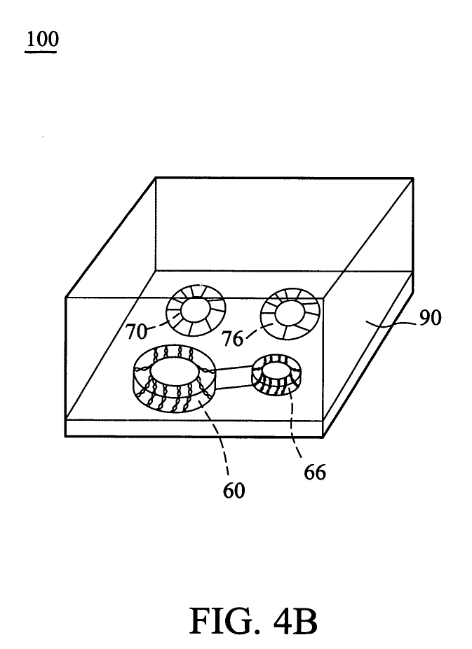

FIG. 4A is a schematic view of an embodiment of a package structure of a transformer prior to the packaging steps. FIG. 4B is a schematic view of an embodiment of a package structure of a transformer when the packaging steps are completed. As shown in FIG. 4A and FIG. 4B, a semi-finished product of the package structure of the transformer is complete when the described transformer module is made. Afterward, a casing 90 having an opening 92 is used to cover and package the semi-finished product so that the second surface 82 of the substrate 50 can be exposed out from the opening 92 of the casing 90. The casing 90 is a metal casing or a plastic casing. Hence, the manufacturing procedure of the transformer module 100 is complete. In addition, a colloid is filled between the casing 90 and the semi-finished product before packaging the semi-finished product of the package structure of the transformer to form an insulating effect for the passive components on the first surface 52 of the substrate 50.

It should be noted that the coils wound on the annular iron core can be general metal coils or enameled wires coated with insulating varnish. The passive component is not limited to a transformer having iron cores wound with more than two coils or only one coil. The passive components can be resistors, capacitors, etc.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A package structure, comprising:
a substrate having a first surface and a second surface opposite to the first surface;
a passive component disposed on the first surface of the substrate; and
a plurality of contacts disposed on the second surface of the substrate.

2. The package structure as claimed in claim 1, wherein the substrate is a printed circuit board.

3. The package structure as claimed in claim 1, wherein the passive component is a transformer, a resistor, or a capacitor.

4. The package structure as claimed in claim 3, wherein the transformer has an annular iron core wound by at least a coil for providing the passive component with power.

5. The package structure as claimed in claim 4, wherein the coil is an enameled wire or a metal coil.

6. The package structure as claimed in claim 4, wherein the substrate further comprises a plurality of metal sheets formed on the first surface to be used as pads of the substrate.

7. The package structure as claimed in claim 6, wherein the coil has at least two outlet terminals welded on the different metal sheets.

8. The package structure as claimed in claim 6, wherein the metal sheets are made of copper or copper alloy.

9. The package structure as claimed in claim 6, wherein the plurality of contacts are positioned corresponding to metal sheets respectively.

10. The package structure as claimed in claim 6, wherein the number of the metal sheets is more than or equal to that of the contacts.

11. The package structure as claimed in claim 1, wherein the contacts are solder balls.

12. The package structure as claimed in claim 1, wherein the contacts are welded on the second surface by ball grid array package techniques.

13. The package structure as claimed in claim 1, further comprising a casing for covering and packaging the substrate, wherein the second surface of the substrate is exposed out of the casing.

14. The package structure as claimed in claim 13, wherein the casing is made of metal or plastic material.

15. The package structure as claimed in claim 13, further comprising a colloid filled between the substrate and the casing.

16. A package method for a passive component, comprising the steps of:
providing a substrate having a first surface and a second surface opposite to the first surface;
disposing the passive component on the first surface of the substrate;
disposing a plurality of contacts on the second surface of the substrate to form a semi-finished product; and
using a casing to cover and package the semi-finished product and expose the second surface of the substrate out of the casing.

17. The package method as claimed in claim 16, wherein the contacts are welded on the second surface by ball grid array techniques.

18. The package method as claimed in claim 16, further comprising a step of filling a colloid between the casing and the semi-finished product before the step of packaging the semi-finished product.

19. The package method as claimed in claim 16, wherein the substrate further comprises a plurality of metal sheets formed on the first surface to be used as pads of the substrate and the plurality of contacts are positioned corresponding to metal sheets, respectively.

20. The package method as claimed in claim 16, wherein the contacts are solder balls.
